(19) United States
(12) Patent Application Publication
(10) Pub. No.: US 2003/0141537 A1
(43) Pub. Date: Jul. 31, 2003

(54) System for multiple input floating gate structures

(76) Inventor: Xiaoju Wu, Irving, TX (US)

Correspondence Address: TEXAS INSTRUMENTS INCORPORATED, P O BOX 655474, M/S 3999, DALLAS, TX, 75265

(21) Appl. No.: 10/322,339

(22) Filed: Dec. 17, 2002

Related U.S. Application Data
(60) Provisional application No. 60/344,513, filed on Dec. 28, 2001.

(51) Int. Cl. H01L 29/788

(52) U.S. Cl. 257/315

(57) ABSTRACT

The present invention provides a system for efficiently producing versatile multiple input floating gate structures. The present invention provides multiple-input floating gate device (100, 400) that has a first input (106, 406) formed in a first active device region (202, 502) and a second input (108, 408) formed in a second active device region (204, 504). A floating gate (200, 500) is disposed upon the first and second inputs, separated from the inputs by a dielectric layer. A device body, formed in a third active device region (210, 506), is coupled to the first and second inputs through the floating gate.

### PRIORITY CLAIM

This patent application claims priority of U.S. Provisional Application No. 60/344,513, filed on Dec. 28, 2001.

### TECHNICAL FIELD OF THE INVENTION

The present invention relates generally to the field of semiconductor devices, and more particularly to a system for producing multiple input floating gate (MIFG) devices in a single poly process.

### BACKGROUND OF THE INVENTION

The continual demand for enhanced integrated circuit performance has resulted in, among other things, a dramatic reduction of semiconductor device geometries, and continual efforts to optimize the performance of every substructure within any semiconductor device. A number of improvements and innovations in fabrication processes, material composition, and layout of the active circuit levels of a semiconductor device have resulted in very high-density circuit designs. Increasingly dense circuit design has not only improved a number of performance characteristics, it has also increased the importance of, and attention to, semiconductor material properties and behaviors. As semiconductor device geometries are continually scaled downward, certain problems arise with fundamental performance characteristics of certain device features.

Consider, for example, a simple MOS-based transistor. One key performance parameter for such a device is its threshold voltage (Vₜ). Generally, Vₜ, as measured across the gate of a transistor, is fixed. The precise value of Vₜ is generally affected by a number of layout and process variables, such as the gate oxide thickness and the dopants utilized. Once a given Vₜ is determined, operation of the transistor may be simplified to the relationship between Vₜ and the gate voltage (V_{g}). Generally, if the magnitude of V_{g} is greater than the magnitude of Vₜ, the transistor will turn on, and vice versa. In larger geometry device processes, this typically posed little concern because the overall device supply voltage was large enough to accommodate even a substantial Vₜ value.

However, as process geometries and, correspondingly, device supply voltages have decreased, large Vₜ values have become more problematic. Typically, Vₜ values do not scale down in proportion to other device features and parameters when process geometries are “shrunken”. Depending upon the magnitude of a geometry reduction, this phenomenon can result in a Vₜ that consumes most of the available supply voltage range. Usually, in purely digital applications fabricated in mature processes, this is still not too much of a concern. Because a purely digital device or structure only needs to turn “off” or “on”, minimal supply voltage range exceeding Vₜ is required to achieve necessary performance. Excessively large Vₜ values, however, still remain problematic for low-power processes, even in purely digital applications. This problem is of even greater concern in the design and fabrication of low-power mixed-signal devices (i.e. devices having both analog and digital circuitry).

Often, the analog portions of mixed-signal devices require some active operating range, commonly referred to as headroom, within which to operate. In situations where Vₜ consumes most or essentially all of a low-power device's supply voltage range, active headroom is minimized or effectively eliminated altogether. This phenomenon causes a number of design and performance problems for mixed-signal devices. Designers of analog circuitry, especially low-power analog circuitry, therefore generally prefer a very low Vₜ value. Furthermore, in some applications it may even be desirable to have a dynamically adjustable Vₜ.

A solution to the excessive Vₜ problem is the use of multiple input floating gate (MIFG) structures. With typical MIFGs, a single transistor is implemented with two or more gates that control the current across the transistor and effectively divide the burden of driving the device past Vₜ. One or more of the gate inputs can be coupled to a constant voltage, while one or more remaining gate inputs are left open for dynamic inputs from other circuitry. Thus, the effective Vₜ at those open inputs is substantially reduced, leaving greater headroom. Depending upon the application, multiple inputs may be left open to provide the ability to dynamically modulate Vₜ for the device. In some applications, the MIFG structure may be configured in such a way as to render Vₜ negative (i.e., depletion mode).

Although, in theory, MIFG structures are very useful, most conventional implementations of such structures typically utilize or require more complex processes (i.e., dual poly processes) for successful implementation. Generally, in these dual poly implementations, a first poly layer is utilized in forming conventional gate structures. The second poly layer, separated from the first poly by some dielectric (e.g., TEOS, Ni, ONO), is then utilized in forming the multiple gate inputs. In some instances, the need for MIFG structures may justify the use of such complex and costly processes. In most designs that could benefit from MIFG structures, however, cost, performance, or fabrication process limitation concerns, in addition to design process complexities, limit, if not preclude, the feasibility of using a dual poly process.

As a result, there is a need for a system for producing multiple input floating gate structures in an easy, efficient and cost-effective manner.

### SUMMARY OF THE INVENTION

The present invention provides a versatile system for producing multiple input floating gate (MIFG) structures in an easy, efficient and cost-effective manner. More specifically, the present invention provides a system for producing MIFG structures in a number of low-cost, high-volume MOS fabrication processes. The present invention provides for MIFG structures in a single poly process, without adding complexity or cost to the design process. The present invention provides multiple input gate structures formed in a separate active region (e.g., moat), with a poly layer used to provide a floating gate between inputs and MOS circuitry. This system renders extremely efficient MIFG structure design practical in a number of low-cost, low-power technologies.

More specifically, the present invention provides a multiple input floating gate device comprising a first input formed in a first active device region and a second input formed in a second active device region. A floating gate disposed upon the first and second inputs, separated therefrom by a dielectric layer. A device body, formed in a third active device region, is coupled to the first and second inputs through the floating gate.

The present invention also provides a MOS transistor, having a dynamically adjustable threshold voltage value, comprising a first input formed in a first active device region and a second input formed in a second active device region. A floating gate is disposed upon the first and second inputs, and separated therefrom by a gate oxide. A device body is formed in a third active device region, and coupled to the first and second inputs through the floating gate.

The present invention further provides a method of producing a semiconductor device, having a dynamically adjustable threshold voltage value. The method includes forming a first input in a first active device region and forming a second input in a second active device region. A floating gate is disposed upon the first and second inputs, with a dielectric layer interposed therebetween. A device body is formed in a third active device region, and coupled to the first and second inputs through the floating gate.

The present invention also provides a method of producing a multiple input floating gate device in a single-poly MOS process. The method includes: providing a substrate upon which the device is to be fabricated; performing n-well or p-well implant on the substrate; utilizing a LOCOS or STI formation for device isolation; optionally performing a high-dose multiple input moat implant; performing threshold implant; performing gate oxidation; performing poly gate deposition; and performing source/drain implantation.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 is an illustration of one embodiment of a multiple input floating gate device according to the present invention;

FIG. 2 is an illustration of one embodiment of the multiple input floating gate device in FIG. 1 according to the present invention;

FIG. 3 is an illustration of one embodiment of the multiple input floating gate device in FIG. 1 according to the present invention;

FIG. 4 is an illustration of one embodiment of a multiple input floating gate device according to the present invention;

FIG. 5 is an illustration of one embodiment of the multiple input floating gate device in FIG. 4 according to the present invention; and

FIG. 6 is an illustrative plot depicting data descriptive of various embodiments of multiple input floating gate devices according to the present invention.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The invention will now be described in conjunction with any memory. The specific embodiments discussed herein are merely illustrative of specific ways to make and use the invention and do not limit the scope of the invention.

The present invention provides a versatile system for producing multiple input floating gate (MIFG) structures in an easy, efficient and cost-effective manner. More specifically, the present invention provides a system for producing MIFG structures in a number of low-cost, high-volume MOS fabrication processes. The present invention provides for MIFG structures in a single poly process, without adding complexity or cost to the design process. The present invention provides multiple input gate structures formed in a separate active region (e.g., moat), with a polysilicon (poly) layer used to provide a floating gate between inputs and MOS circuitry. In the present invention, a standard MOS gate oxide may be used as a dielectric between the input and floating gates. This system renders extremely efficient MIFG structure design practical in a number of low-cost, low-power technologies.

In contrast to the present invention, conventional MIFG structures are, typically, designed and fabricated in processes having more complex, multi-poly/dielectric, modules that are used to build the multiple input gates and provide isolation between the input and the floating gates. These modules are often not available in many of the high-volume, low-cost, fabrication technologies.

According to the present invention, however, MIFG structures are designed and fabricated using standard, low-cost, MOS processes without such complex modules. Conventional poly 2 input gate structures are replaced with moat region structures, and the dielectric between the input and floating gates is replaced with standard MOS gate oxide.

Utilizing the MIFG structures of the present invention, designers—especially mixed signal designers—are able to fine tune Vₜ. This provides designers the ability to design for maximum headroom, especially in low power applications (e.g., 1.8 or even 1.0 volts). In some cases, the value of the effective Vₜ may even be rendered negative (i.e., depletion mode), improving noise characteristics of the design. Of critical importance, however, is capacitance matching between the floating gates. Most often, capacitance matching is addressed in device layout, as capacitance is functionally related to area of the gates. If gate capacitances are not properly matched, dynamic control of Vₜ will be complex, as Vₜ will not vary in a regular (i.e., linear) fashion. This will complicate designs relying on dynamic Vₜ control. Alternatively, however, this aspect may be exploited should a non-linear variance in Vₜ be desired.

In some embodiments of the present invention, multiple gates are laid out as copies of a single base gate to ensure perfect matching. Furthermore, to reduce moat depletion effects, highly doped moat regions may be used, if available. In the alternative, or in addition, to utilizing highly doped moat regions, poly fingers with minimum channel lengths may be utilized.

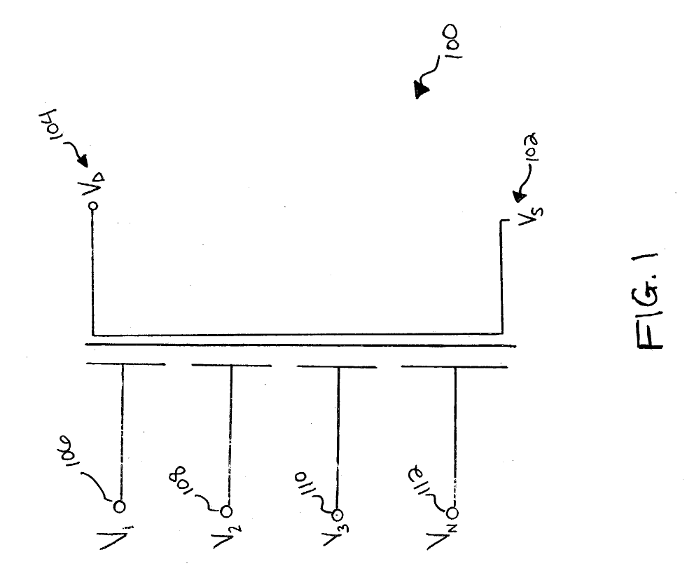

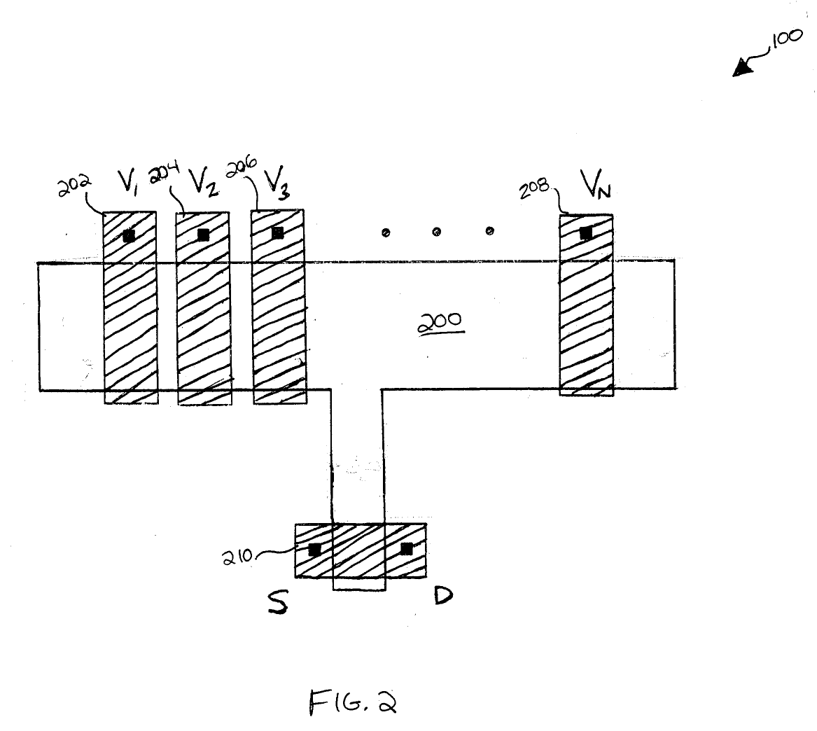

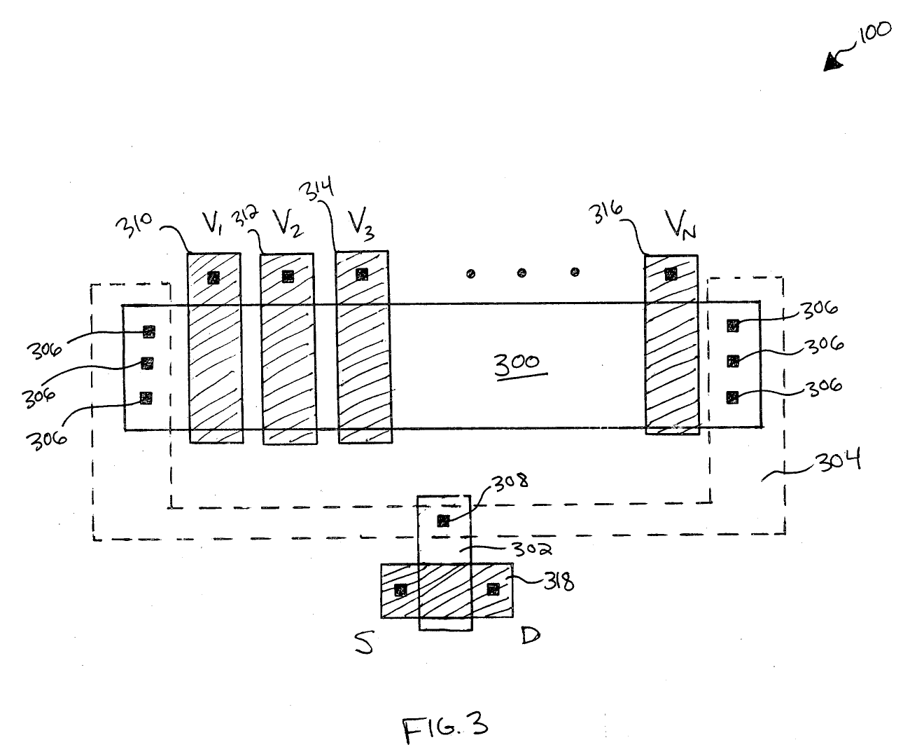

All such aspects are now discussed in greater detail with reference to the illustrative embodiments depicted in FIGS. 1-6. Referring now to FIG. 1, a simple conceptual illustration of an MIFG structure 100 according to the present invention is depicted. Structure 100 is a MOS transistor, comprising a source 102 and drain 104. Structure 100 further comprises a first input 106, second input 108, third input 110, and Nth input 112. FIGS. 2 and 3 illustrate alternative top-view layouts of structure 100. In the embodiment illustrated in FIG. 2, a poly region 200 is formed as a floating gate. Multiple input gates 106-112 are implemented as multiple active area (moat) regions 202-208, respectively. Source 102 and drain 104 (the MOS body) are implemented in moat region 210. Floating gate 200 is laid out to effectively and efficiently couple regions 202-210, and interposed therebetween (not shown) is an appropriate material (e.g, gate oxide) to serve a dielectric function.

In an alternative embodiment, illustrated in FIG. 3, separate poly regions 300 and 302 are formed as floating gates. Regions 300 and 302 are intercoupled by one or more metal interconnect(s) 304, having contacts 306 and 308, respectively, therewith. Multiple input gates 106-112 are implemented as multiple active area (moat) regions 310-316, respectively. Source 102 and drain 104 are implemented in moat region 318. Interposed between the poly and moat regions (not shown) is an appropriate material (e.g, gate oxide) to serve a dielectric function.

In the above embodiments of structure 100, poly regions 200, 300 and 302 may be laid out in minimum width “finger” configurations to enhance performance. To further reduce depletion effects in the multiple input moat regions, source/drain implants may be introduced to the regions. In processes where deep p+ or n+wells are available, such areas may be used for the multiple input region(s) to further reduce depletion effects.

In order to address the Vₜ linearity issues discussed above, regions 202-208, or regions 310-316, may be laid out as identical moat “fingers”—matched perfectly by, for example, replicating copies of a single moat finger. For structure 100, the voltage on the floating gate may be expressed as:

$${V}_{fg} = {\sum }_{i}^{N} ( {C}_{i} / {C}_{T} ) \times {V}_{i} ; \qquad ( 1 )$$

where

Cᵢ is the capacitance for input i, Vᵢ is the voltage at input i, and C_{T}, the total capacitance, is given by

$${C}_{T} = {\sum }_{i}^{N} {C}_{i} \qquad ( 2 )$$

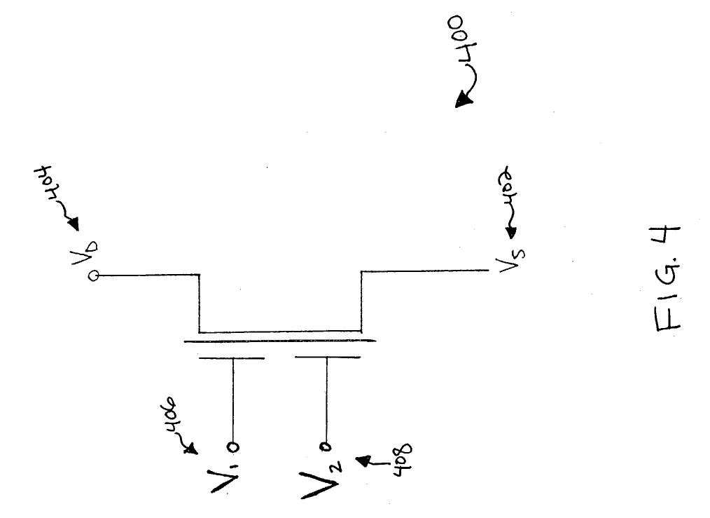

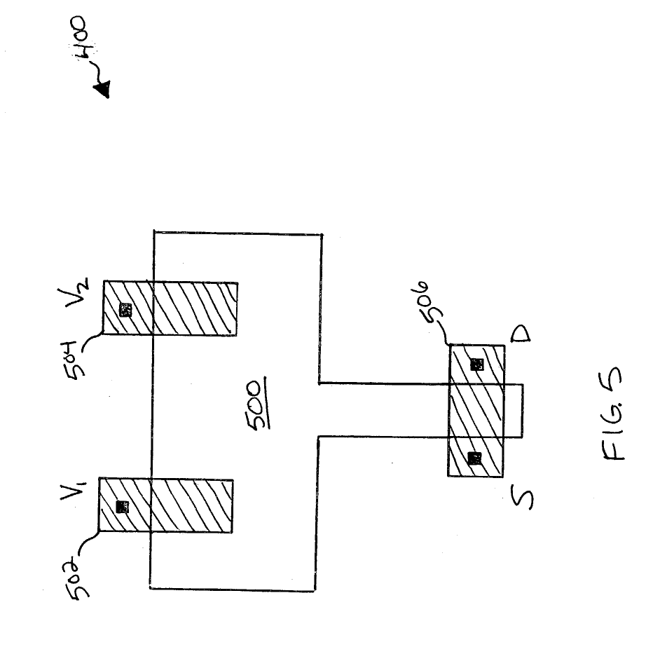

In the field of mixed signal design, one especially useful instance of structure 100 is a two (2) input MIFG. This embodiment is illustrated in reference now to structure 400 of FIG. 4. Structure 400 is a MOS transistor, comprising a source 402 and drain 404. Structure 400 further comprises a first input 406 and a second input 408. FIG. 5 illustrates an illustrative top-view layout of structure 400. In the embodiment illustrated in FIG. 5, a poly region 500 is formed as a floating gate. Input gates 406 and 408 are implemented as multiple active area (moat) regions 502 and 504, respectively. Source 402 and drain 404 are implemented in moat region 506. Floating gate 500 is laid out to effectively and efficiently couple regions 502-506, and interposed therebetween (not shown) is an appropriate material (e.g, gate oxide) to serve a dielectric function

In the above embodiment of structure 400, poly region 500 may be laid out in a minimum width finger configuration to enhance performance. To further reduce depletion effects in the multiple input moat region, source/drain implants may be introduced. In processes where deep p+ or n+wells are available, such areas may be used for the multiple input region to further reduce depletion effects. In order to address the Vₜ linearity issues discussed above, regions 502 and 504 may be laid out as identical moat “fingers”—matched perfectly by, for example, replicating copies of a single moat finger.

Structures in accordance with the present invention, such as structure 400, may be useful in a number mixed-signal devices and applications, including: low Vₜ MOS structures for providing large signal swing; depletion MOS structures for providing lower noise; and resistors having improved linearity. As an example, a low low Vₜ MOS transistor may be formed in accordance with structure 400, where one of the voltage inputs (V₂) is utilized to modulate the characteristics of the other input (V₁). This application exploits the capacitive coupling of the first and second input gates.

In this example, it is assumed that the standard MOS threshold is Vₜ₀. The threshold voltage of the first input (Vₜ₁) may then be derived from equation (1), above, as:

Vₜ₁=[1+(C₂+C₀)/C₁]×Vₜ₀−C₂/C₁×V₂ (3)

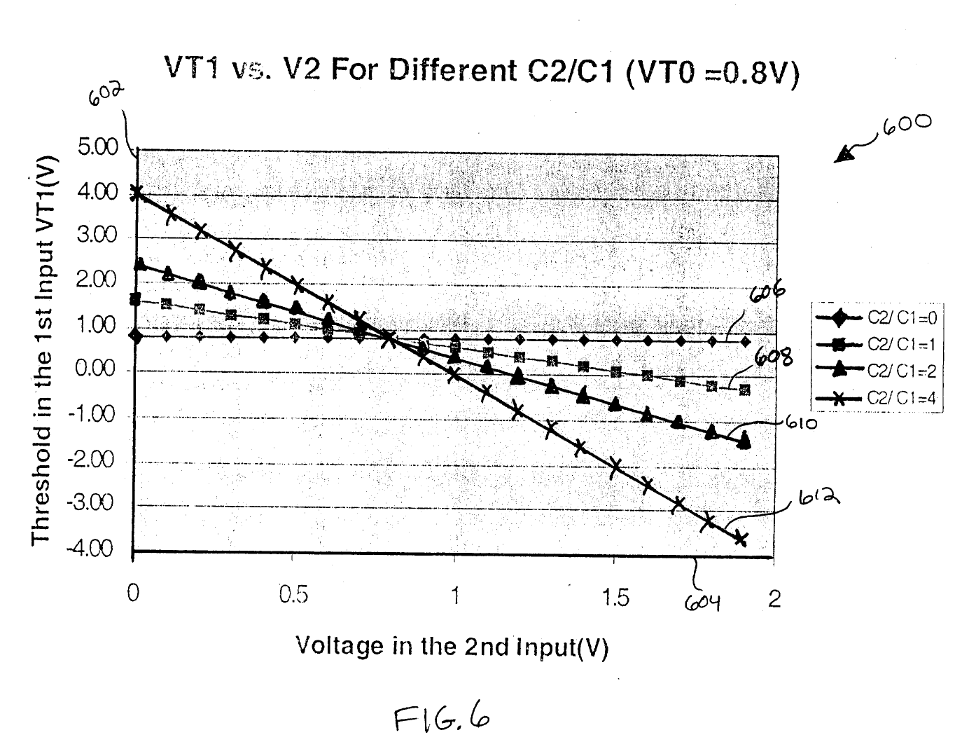

Thus, the threshold voltage for the first input is determined by the ratio of C₂/C₁, C₀/C₁ and, importantly, it may also be modulated by the voltage on the second input (V₂). This relationship is hereafter described in greater detail with reference to FIG. 6. In most common cases, C₂>>C₀, thus the relationship expressed in equation (3) may be rewritten as:

Vₜ₁=[1+(C₂/C₁)]×Vₜ₀−C₂/C₁×V₂

When, in the layout and design of structure 400, the same gate oxide is used to separate the poly from the input gates and the MOS body, then C₂/C₁=A₂/A₁ (i.e., the area ratio).

Referring now to FIG. 6, an illustrative plot 600 of Vₜ₁ as a function of V₂ for differing C₂/C₁, assuming a Vₜ₀ value of 0.8 volts, is depicted. Plot axis 602 depicts the value of Vₜ₁, while plot axis 604 depicts the value of V₂. Plot lines 606-612 represent the results for (C₂/C₁) values of 0, 1, 2 and 4, respectively. As illustrated, depletion mode for Vₜ₁ is possible when V₂≧[1+(C₂/C₁)]×Vₜ₀.

The teachings of the present invention may be readily implemented in a number of design flows and process technologies. For illustrative purposes, however, the structures disclosed above may be formed by: performing n-well and p-well implant; utilizing a LOCOS or STI formation for device isolation; optionally performing a high-dose (e.g., >1E15) multiple input moat implant; performing Vₜ implants for standard MOS transistors; performing gate oxidation and poly gate deposition; performing LDD and S/D implantation; and performing other necessary or desired back-end processing with multiple level metal and passivation.

The embodiments and examples set forth herein are presented to best explain the present invention and its practical application and to thereby enable those skilled in the art to make and utilize the invention. However, those skilled in the art will recognize that the foregoing description and examples have been presented for the purpose of illustration and example only. The description as set forth is not intended to be exhaustive or to limit the invention to the precise form disclosed. Many modifications and variations are possible in light of the above teaching without departing from the spirit and scope of the following claims.

What is claimed is:

1. A multiple input floating gate device comprising:
a first input formed in a first active device region;
a second input formed in a second active device region;
a floating gate disposed upon the first and second inputs and separated therefrom by a dielectric layer; and
a device body, formed in a third active device region and coupled to the first and second inputs through the floating gate.

2. The device of claim 1, wherein the floating gate is formed of silicon.

3. The device of claim 1, wherein each of the first and second active device regions are formed as a moat.

4. The device of claim 1, wherein the third active device region is formed as a moat.

5. The device of claim 1, wherein the dielectric layer is a gate oxide.

6. The device of claim 1, wherein the floating gate is formed as a single contiguous body disposed upon the device body and the first and second inputs.

7. The device of claim 1, wherein the floating gate is formed as multiple bodies, disposed over the first, second and third active device regions, coupled together by an interconnect.

8. The device of claim 7, wherein the interconnect comprises a metal layer.

9. The device of claim 1, wherein the device functions as a transistor.

10. The device of claim 1, wherein each input is of identical size and shape.

11. A MOS transistor, having a dynamically adjustable threshold voltage value, comprising:
a first input formed in a first active device region;
a second input formed in a second active device region;
a floating gate disposed upon the first and second inputs and separated therefrom by a gate oxide; and
a device body, formed in a third active device region and coupled to the first and second inputs through the floating gate.

12. A method of producing a semiconductor device having a dynamically adjustable threshold voltage value, comprising the steps of:
forming a first input in a first active device region;
forming a second input in a second active device region;
disposing a floating gate upon the first and second inputs with a dielectric layer interposed therebetween; and
forming a device body in a third active device region, coupled to the first and second inputs through the floating gate.

13. The method of claim 12, wherein the semiconductor device is produced in a single-poly fabrication process.

14. The method of claim 12, wherein the floating gate is formed of polysilicon.

15. The method of claim 12, wherein each of the first and second active device regions are formed as a moat.

16. The method of claim 12, wherein each active device region is of identical size and shape.

17. The method of claim 12, wherein the third active device region is formed as a moat.

18. The method of claim 12, wherein the floating gate is formed as a single contiguous body disposed upon the device body and the first and second inputs.

19. The method of claim 12, wherein the floating gate is formed as multiple bodies disposed over the first, second and third active device regions, and coupled together by an interconnect.

20. A method of producing a multiple input floating gate device in a single-poly MOS process, comprising the steps of:
providing a substrate upon which the device is to be fabricated;
performing n-well or p-well implant on the substrate;
utilizing a LOCOS or STI formation for device isolation;
optionally performing a high-dose multiple input moat implant;
performing threshold implant;
performing gate oxidation;
performing poly gate deposition; and
performing source/drain implantation.
